(19) United States
(12) Patent Application Publication
(10) Pub. No.: US 2025/0225626 A1
(43) Pub. Date: Jul. 10, 2025

(54) METHOD AND DEVICE WITH SEMICONDUCTOR PATTERN GENERATION

(71) Applicant: SAMSUNG ELECTRONICS CO., LTD., Suwon-si (KR)

(72) Inventors: Seong-Jin Park, Suwon-si (KR); Haedong Jeong, Suwon-si (KR)

(73) Assignee: SAMSUNG ELECTRONICS CO., LTD., Suwon-si (KR)

(21) Appl. No.: 19/006,678

(22) Filed: Dec. 31, 2024

(30) Foreign Application Priority Data
Jan. 4, 2024 (KR) 10-2024-0001773

(51) Int. Cl. G06T 5/70; G06T 5/60

(52) U.S. Cl. CPC G06T 5/70; G06T 5/60; G06T 2207/20076; G06T 2207/20081

(57) ABSTRACT

A method with semiconductor pattern generation includes generating a first image by performing a first sequence of restorative operations, of a generative model that is initially provided an input image, based on a first set restoration process, wherein the generative model is a circuitry pattern-based generative model having a plurality of restorative operations, generating a second image by performing a second sequence of restorative operations, of the generative model and continuing from the first image, based on the first set restoration process, and generating, dependent on a determined similarity between the first image and the second image, a final semiconductor pattern by performing multiple restorative operations, of the generative model continuing from the second image, that include a third sequence of restorative operations of the generative model based on a second set restoration process that is different from the first set restoration process.

### CROSS-REFERENCE TO RELATED APPLICATION

This application claims the benefit under 35 USC § 119(a) of Korean Patent Application No. 10-2024-0001773 filed in the Korean Intellectual Property Office on Jan. 4, 2024, the entire disclosure of which are incorporated herein by reference for all purposes.

### BACKGROUND

### 1. Field

The disclosure relates to a method and device with semiconductor pattern generation.

### 2. Description of the Related Art

Patterns of a semiconductor chip may be formed by a photolithography process and an etching process. A pattern layout of circuit patterns for a semiconductor chip may be designed and the corresponding circuit patterns may be transferred from a mask onto the wafer through a photolithography process. Through this process, gaps or differences may occur between a circuit pattern transferred onto the wafer and the original designed circuit pattern. For example, such gaps or differences may occur due to an optical proximity effect in the photolithography process and/or a loading effect in the etching process. Attempts to more accurately transfer the circuit pattern on the mask onto the wafer have been made using technologies such as Process Proximity Correction (PPC) and Optical Proximity Correction (OPC) that may take into consideration a deformation of the transferred circuit pattern on the wafer.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a processor-implemented method includes generating a first image by performing a first sequence of restorative operations, of a generative model that is initially provided an input image, based on a first set restoration process, wherein the generative model is a circuitry pattern-based generative model having a plurality of restorative operations, generating a second image by performing a second sequence of restorative operations, of the generative model and continuing from the first image, based on the first set restoration process, and generating, dependent on a determined similarity between the first image and the second image, a final semiconductor pattern by performing multiple restorative operations, of the generative model continuing from the second image, that include a third sequence of restorative operations of the generative model based on a second set restoration process that is different from the first set restoration process.

The first set restoration process may include performing a corresponding restoration operation of the generative model by performing denoising on a current image and then adding random noise to a result of the denoising, and the second set restoration process may include performing a different corresponding restoration operation of the generative model by performing the denoising without the adding of the random noise to the result of the denoising.

The method may further include performing the determining of the similarity between the first image and the second image respectively based on a first feature extracted from the first image and a second feature extracted from the second image, and determining whether the similarity meets a predetermined level, wherein the generating of the final semiconductor pattern may include, when a result of the determining of whether the similarity meets the predetermined level is that the similarity meets the predetermined level, performing the third sequence of restorative operations of the generative model continuing from the second image, such that a final restorative operation of the third sequence is a final restorative operation of the generative model that outputs the final semiconductor pattern, and, when the result of the determining of whether the similarity meets the predetermined level is that the similarity does not meet the predetermined level, generating respective third images by performing subsequent restorative operations, of the multiple restorative operations and continuing from the second image, based on the first set restoration process and prior to the third sequence of operations.

The generating of the final semiconductor pattern may include, when a performed similarity determination between one of the respective third images and a subsequent one of the respective third images is determined to not meet a predetermined minimum level, ceasing the performing of the subsequent restorative operations and begin performing the third sequence of restorative operations of the generative model continuing from the third image, such that the final restorative operation of the third sequence is the final restorative operation of the generative model that outputs the final semiconductor pattern.

The method may further include performing the determining of the similarity between the first image and the second image by extracting a first feature and a second feature from the first image and the second image, respectively, converting the first feature and the second feature into a first feature vector and a second feature vector, respectively, measuring the similarity between the first image and the second image by comparing the first feature vector with the second feature vector, assigning a similarity score to a result of the measuring, and determining whether the similarity score meets a predetermined threshold, and in response to the similarity score being determined to meet the predetermined threshold, determining that the first image and the second image are similar, and performing the third sequence of restorative operations of the generative model continuing from the second image, such that a final restorative operation of the third sequence is a final restorative operation of the generative model that outputs the final semiconductor pattern.

The measuring of the similarity between the first image and the second image may include measuring a similarity between the first feature vector and the second feature vector through at least one of Euclidean Distance, Cosine Similarity, and Manhattan Distance-based measurements.

The plurality of restorative operations of the generative model may be respectively differently timed restorative operation steps, from a first restorative operation step to intermediary restorative operation steps to a final restorative operation step that corresponds to a final restorative operation of the generative model, and a sequencing of corresponding restorative operations, of the generative model when implemented based on the first set restoration process, may be according to a first time step length that is different from a second time step length of the second set restoration process that defines a sequencing of other corresponding restorative operations of the generative model when implemented based on the second set restoration process.

The second time step length may be longer than the first time step length.

The method may further comprise performing the determining of the similarity between the first image and the second image by respectively extracting a first feature from the first image and a second feature from the second image and comparing the first feature to the second feature, where the first feature and the second feature may each include at least one of color, texture, shape, boundary, detailed pattern, or feature point.

The method may further include performing the determining of the similarity between the first image and the second image by respectively extracting a first feature from the first image and a second feature from the second image and comparing the first feature to the second feature, where the first feature and the second feature may each include a semantic feature.

The method may further include setting a first variable in a memory to store a value of a time step at which a restorative operation of the generative model based on the second set restoration process is set to proceed, maintaining a second variable in the memory to represent decrementing integer values for current time steps of respective restorative operations of the generative model as the plurality of restorative operations are being performed, and performing the third sequence of the generative model when the second variable reaches the first variable.

In a general aspect, a processor-implemented method includes setting a variable in a memory to store a value of a time step at which a reverse process of a diffusion model is configured to proceed, wherein the diffusion model is trained with a semiconductor pattern image, and generating a final semiconductor pattern by executing the reverse process of the diffusion model, including comparing a first value representing a time step of a current step in the reverse process of the diffusion model with the value stored in the variable, when the first value is greater than the value stored in the variable, restoring a next step image by performing denoising on a current step image and adding random noise to a result of the denoising performed on the current step image, based on a first set restoration process, and when the first value is less than or equal to the value stored in the variable, restoring the next step image by performing the denoising on the current step image, without performing the adding of the random noise to the result of the denoising, based on a second set restoration process different from the first set restoration process.

The setting of the value of the variable may include setting the value of the variable to a predetermined value representing a ratio of time steps performed based on the first set restoration process and the second set restoration process.

The reverse process of the diffusion model may be configured to proceed with a total set number of time steps, wherein the method may further include generating a k-th step image by repeating, with incremented integer decrements of n from the total set number until n equals k, a first reverse restoration process of the diffusion model based on the first set restoration process to generate an (n−1)-th step image from an n-th step image, wherein n and k are integers, generating a (k−j)-th step image by another repeating, with incremented integer decrements of n from k until n equals (k−j), of the first reverse restoration process of the diffusion model based on the first set restoration process, wherein j is an integer, and determining a similarity between the k-th step image and the (k−j)-th step image by extracting a first feature from the k-th step image, extracting a second feature from the (k−j)-th step image, and comparing the first feature and the second feature, where the setting of the variable in the memory to store the value of the time step may include, when it is determined that the similarity is a predetermined level or more, setting the value of the variable to k−j.

The method may further include, when it is determined that the similarity fails to meet the predetermined level, generating a (k−j−m)-th step image by an additional repeating, with incremented integer decrements of n from (k−j) until n equals (k−j−m), of the first reverse restoration process of the diffusion model based on the first set restoration process, wherein m is an integer, and performing a similarity determination between the (k−j−m)-th step image and a subsequent step image.

The method may further include, when it is determined that the similarity between the (k−j−m)-th step image and the subsequent step image fails to meet a predetermined minimum level, specifying a value of m as a value that is a predetermined minimum value or more.

In a general aspect, a computing device includes one or more processors configured to generate a first image through performance of a first sequence of restorative operations, of a generative model that is initially provided an input image, based on a first set restoration process, wherein the generative model is a circuitry pattern-based generative model having a plurality of restorative operations, generate a second image through performance of a second sequence of restorative operations, of the generative model and continuing from the first image, based on the first set restoration process, and generate, dependent on a determined similarity between the first image and the second image, a final semiconductor pattern through performance of multiple restorative operations, of the generative model continuing from the second image, that include a third sequence of restorative operations of the generative model based on a second set restoration process that is different from the first set restoration process.

The first set restoration process may include performance of a corresponding restoration operation of the generative model through performance of a denoising on a current image and then an addition of random noise to a result of the denoising, and the second set restoration process may include performance of a different corresponding restoration operation of the generative model through performance of the denoising without the addition of the random noise to the result of the denoising.

The one or more processors may be further configured to perform the determination of the similarity between the first image and the second image respectively based on a first feature extracted from the first image and a second feature extracted from the second image, and determining whether the similarity meets a predetermined level, and, for the generating of the final semiconductor pattern, the one or more processors may be configured to, when a result of the determining of whether the similarity meets the predetermined level is that the similarity meets the predetermined level, perform the third sequence of restorative operations of the generative model continuing from the second image, such that a final restorative operation of the third sequence is a final restorative operation of the generative model that outputs the final semiconductor pattern, when the result of the determining of whether the similarity meets the predetermined level is that the similarity does not meet the predetermined level, generating respective third images by performing subsequent restorative operations, of the multiple restorative operations and continuing from the second image, based on the first set restoration process and prior to the third sequence of operations, and when a performed similarity determination between one of the respective third images and a subsequent one of the respective third images is determined to not meet a predetermined minimum level, cease the performing of the subsequent restorative operations and perform the third sequence of restorative operations of the generative model continuing from the subsequent one of the respective third images.

The one or more processors may be further configured to perform the determination of the similarity between the first image and the second image through an extraction of a first feature and a second feature from the first image and the second image, respectively, a conversion of the first feature and the second feature into a first feature vector and a second feature vector, respectively, a measurement of the similarity between the first image and the second image through a comparison of the first feature vector with the second feature vector, an assignment of a similarity score to a result of the measuring, and determine whether the similarity score meets a predetermined threshold, and, in response to the similarity score being determined to meet the predetermined threshold, a determination that the first image and the second image are similar, and a performance of the third sequence of restorative operations of the generative model continuing from the second image, such that a final restorative operation of the third sequence is a final restorative operation of the generative model that outputs the final semiconductor pattern.

For the measuring of the similarity between the first image and the second image, the one or more processors may be configured to measure a similarity between the first feature vector and the second feature vector through at least one of Euclidean Distance, Cosine Similarity, and Manhattan Distance-based measurements.

Other features and aspects will be apparent from the following detailed description, the drawings, and the claims.

### BRIEF DESCRIPTION OF THE DRAWINGS

FIG. 1 illustrates an example semiconductor pattern generation process of a computing device according to one or more embodiments.

FIG. 2 illustrates an example method with semiconductor pattern generation according to one or more embodiments.

FIG. 3 is a flowchart of an example method with a semiconductor pattern generation according to one or more embodiments.

FIG. 4 is a flowchart of an example method with a semiconductor pattern generation according to one or more embodiments.

FIGS. 5 to 8 illustrate example implementation results of semiconductor pattern generation according to one or more embodiments.

FIG. 9 illustrates an example electronic device according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order (e.g., a certain order). Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

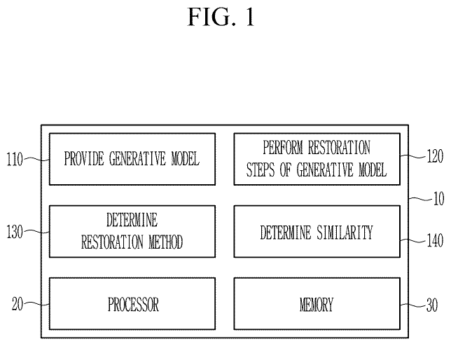

FIG. 1 illustrates an example semiconductor pattern generation process of a computing device according to one or more embodiments.

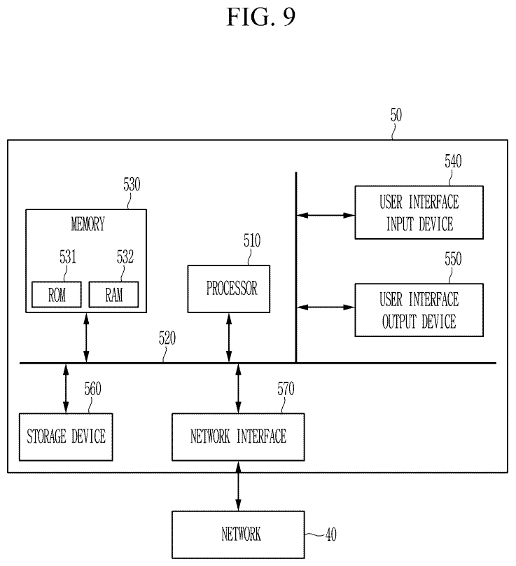

Referring to FIG. 1, a computing device 10 may comprise one or more memories 30 and one or more processors 20. As a non-limiting example, the computing device 10 may be the electronic device 50 as described below with reference to FIG. 9. For example, the one or more processors 20 may correspond to the one or more processors 510 of the electronic device 50, and the one or more memories 30 may correspond to the one or more memories 530 of the electronic device 50.

The computing device 10 may be configured to perform a model providing operation 110 (e.g., to the one or more processors 20) of providing a generative model, reverse process operations 120 (e.g., by any one or any combination of the one or more processors 20) of performing restoration steps of the generative model, similarity determining operations 140 (e.g., by any one or any combination of the one or more processors 20) of determining respective similarities between step results of different performances of the reverse process operations 120, and restoration method determining operations 130 (e.g., by any one or any combination of the one or more processors 20) of determining respective restoration methods for the reverse process operations 120 based on corresponding results of the similarity determining operations 140.

The model providing operation 110 may prepare the generative model (e.g., a diffusion model) trained with a semiconductor pattern image. The generative model may be stored in any one of the one or more memories 30 and/or may be loaded from the any of the one or more memories 30 into another any of the one or more memories 30 to be provided to any of the one or more processors 20 for implementing the generative model to generate the semiconductor pattern. While examples are not limited to the same, for explanatory purposes, examples below will be provided based on the generative model being the diffusion model. Accordingly, any or any combination of the one or more processors 20 may be configured to perform any one or any combination of operations described herein, including any or all of the model providing operation 110, reverse process operations 120, restoration method determining operations 130, and similarity determining operations 140, as non-limiting examples. For example, the one or more processors 20 may be configured to execute instructions that may be stored in any of the one or more memories 30, such that execution of the instructions by the one or more processors 20 configure the one or more processors 20 to perform any or any combination of the operations described herein, including any or all of the model providing operation 110, reverse process operations 120, restoration method determining operations 130, and similarity determining operations 140, as non-limiting examples.

A diffusion model or a diffusion probabilistic model is a type of generative model, and may model a process of generating data as a diffusion process. Specifically, a diffusion model may be trained to have generative and restorative properties by first performing a forward process through a noise adding diffusion model that incrementally transforms input data (e.g., an input image) to generated complete noise, as only an example, by repeating a stepped process of gradually (e.g., from 0-th through T-th steps) adding noise to the data. The diffusion model having generative and restorative properties may be trained through a reverse stepped process that regenerates the data by repeating a stepped process of gradually (e.g., from T′-th through 0-th steps) restoring or denoising the complete noise. In a typical simplest approach, T′ may equal T, so there may be same number of restorative (or denoising) steps in the diffusion model with generative and restorative properties as the number of noise adding steps in the noise adding diffusion model. For example, the noise adding diffusion model may add noise to an input image I₀ and incrementally add noise for each time step t until the final image I_{T} is generated, and the diffusion model with generative and restorative properties may input image I_{T} and incrementally restore (or denoise) for each time step t until a final image I_{F} is generated. Likewise, in the typical simplest approach, the diffusion model with generative and restorative properties may be trained so image I_{F} is the same as image I₀, or image I_{F} may be slightly or substantially different from image I₀ based upon conditional or other information that is also considered by the diffusion model with generative and restorative properties. As a non-limiting example, each step of the noise adding diffusion model may include a set of AI or other machine-learning components, such as plural neural network layers as non-limiting examples, configured to each add noise to data input to that set of AI or other machine learning components, such that with each set of the AI or other machine-learning components follows a previous set of the AI or other machine-learning components, that respectively perform the incremental noise adding. As a non-limiting example, each step of the diffusion model with generative or restorative properties may include another set of AI or other machine-learning components, such as plural neural network layers as non-limiting examples, configured to each remove noise from data input to that set of other AI or other machine learning components, such that with each set of the other AI or other machine-learning components follows a previous set of the other AI or other machine-learning components, that respectively perform the incremental restoration or noise removing. Hereinafter, for ease of explanation, the noise adding diffusion model may be referred to as a forward process, forward, diffusion process, forward diffusion model, etc., and the diffusion model with generative and restorative properties may be referred to as a reverse process, a reverse diffusion process, a generative reverse diffusion process, generative reverse diffusion model, etc.

The model providing operation 110 may prepare and provide the generative reverse diffusion model trained with the reverse process of restoring original semiconductor pattern image data from an input semiconductor pattern image data to which noise has been added. In an example, the generative reverse diffusion model may be trained to generate new data corresponding to the original semiconductor pattern image from data to which noise is added as a semiconductor pattern image including microstructures of a semiconductor chip, for example, various hardware component parts such as a gate pattern that constitutes a transistor, an interconnect that connects elements inside the semiconductor chip to each other and provides a path of current, a contact hole used to connect an upper layer and a lower layer, a memory cell pattern with a data storage function, a power rail that distributes power to the semiconductor chip, etc.

The reverse process operation 120 may set a total of n steps (where n is an integer greater than 1) to perform the reverse process of the generative reverse diffusion model, and the restoration method determining operation 130 may set the current restoration method to a first restoration method, which may also be referred to herein as a first set restoration process. Here, the first restoration method may include a method of restoring a next step image by performing denoising (removing noise) on the current step image and then adding random noise. Subsequently, the reverse process operation 120 may restore an (n−1)-th step image from an n-th step image that starts the reverse process based on the first restoration method set by the restoration method determining operation 130. Here, the value of n may be set to a determined appropriate value according to a purpose of implementation, an implementation environment, etc. That is, the reverse process operation 120 may remove one step of noise from the n-th step image that starts the reverse process, then add random noise before completing a restoration step, and restore the image to which the random noise has been added as the (n−1)-th step image.

The reverse process operation 120 may then repeat restoration based on the first restoration method until a k-th step image (where k is an integer of n−1 or less) is eventually obtained from the (n−1)-th step image. Here, the value of k may be set to a determined appropriate value according to a purpose of implementation, an implementation environment, etc., and, in particular, performance and efficiency may be considered in terms of generating a semiconductor pattern through the generative reverse diffusion model.

The similarity determining operation 140 may obtain a first feature by performing feature extraction on the k-th step image. In some embodiments, the first feature may include at least one of color, texture, shape, boundary, detailed pattern, and feature point. In some other embodiments, the first feature may include a semantic feature. Here, the semantic feature may be a feature that represents the meaning or content of an object expressed by an image.

The reverse process operation 120 may then repeat restoration until a (k−j)-th step image (where j is an integer greater than 0) is eventually obtained from the k-th step image based on the first restoration method. Here, the value of j may be set to a determined appropriate value according to a purpose of implementation, an implementation environment, etc., and, in particular, performance and efficiency may be considered in terms of generating a semiconductor pattern through the generative reverse diffusion model.

The similarity determining operation 140 may obtain a second feature by performing feature extraction on the (k−j)-th step image. In some embodiments, the second feature, like the first feature, may include at least one of color, texture, shape, boundary, detailed pattern, and feature point. In some other embodiments, the second feature, like the first feature, may include the semantic feature.

In some embodiments, feature extraction may be accomplished by using a separate feature extraction model, or may be accomplished by utilizing internal features used in the generative reverse diffusion model.

The similarity determining operation 140 may then determine a similarity between the k-th step image and the (k−j)-th step image based on the first feature and the second feature. In some embodiments, the similarity determining operation 140 may measure the similarity by converting the first feature into a first feature vector and converting the second feature into a second feature vector, and comparing the first feature vector with the second feature vector. Also, the similarity determining operation 140 may assign a similarity score to a measurement result, and, when the similarity score meets a predetermined threshold (e.g., is the predetermined threshold or more), determine that the k-th step image and the (k−j)-th step image are similar.

In some embodiments, measuring the similarity by comparing the first feature vector with the second feature vector may include measuring the similarity between the first feature vector and the second feature vector through at least one of Euclidean Distance, Cosine Similarity, and Manhattan Distance-based methods. Euclidean distance-based similarity measurement may be a method of measuring a straight line distance between the first feature vector and the second feature vector, and cosine similarity-based similarity measurement may be a method of measuring an angle between the first feature vector and the second feature vector and focusing on directionality. Manhattan distance-based similarity measurement may be a method of measuring a distance (i.e., Manhattan distance) between the first feature vector and the second feature vector measured along a grid-shaped path.

When the similarity determining operation 140 determines that the similarity is higher than a predetermined level, the restoration method determining operation 130 may set the current restoration method as a second restoration method, which may also be referred to herein as a second set restoration process, that is different from the first restoration method. Here, the second restoration method may include a method of restoring a next step image by only performing denoising on a current step image. That is, the second restoration method may be a method of restoring the current step image from which noise has been removed by one step as the next step image without adding random noise. The reverse process operation 120 may then repeat restoration until a 0-th step image, as a non-limiting example, is eventually restored from the (k−j)-th step image based on the second restoration method. Here, as such a non-limiting example, the 0-th step image may be a finally generated semiconductor pattern image output by the generative reverse diffusion model.

In particular, a time step length of the first restoration method may be different from a time step length of the second restoration method. For example, a second time step may be a subset of a first time step. Accordingly, the interval of second time steps may be set longer than the interval of first time steps. Herein, while examples have been given where the steps of each of the forward diffusion model and the generative reverse diffusion model have been explained as being time dependent, i.e., respectively correlated to steps of set units of time, such as the first set unit of time of the example first restoration method and the different second set unit of time of the example second restoration method, such examples are for explanative purposes only and such steps may not be units of time but merely respective strides or other scheduled divisions of the whole or sub-whole portions of the aforementioned total number of T or T′ steps of the forward diffusion model or as originally trained generative reverse diffusion model.

Unlike when the similarity determining operation 140 determines that the similarity is higher than a predetermined level, when the similarity determining operation 140 determines that the similarity fails to meet the predetermined threshold (e.g., is less than the predetermined level), the reverse process operation 120 may repeat restoration until a (k−j−m)-th step image (where m is an integer greater than 0) is eventually obtained from the (k−j)-th step image based on the first restoration method. Here, the value of m may be set to a determined appropriate value according to a purpose of implementation, an implementation environment, etc., and, in particular, performance and efficiency may be considered in terms of generating a semiconductor pattern through the generative reverse diffusion model. Meanwhile, the similarity determining operation 140 may re-perform similarity determination on the (k−j−m)-th step image and a subsequent step image.

In some embodiments, similarity may be considered to determine the value of m. Specifically, when the similarity is determined to have failed to meet a predetermined minimum level (e.g., is determined to be less than the predetermined minimum level), the value of m may be specified as a value that is a predetermined minimum value or more. For example, if a value representing the minimum level of similarity is S_{M} and the minimum value is i_{M}, when the similarity between the k-th step image and the (k−j)-th step image determined by the similarity determining operation 140 does not reach S_{M} that is the minimum level of similarity, the value of m may be set to a sufficiently large value (i.e., a value at least equal to or greater than the minimum value i_{M}). Accordingly, because the similarity between the k-th step image and the (k−j)-th step image is not high, when the similarity determination is re-performed in a subsequent step, the number of re-performing may be controlled not to unnecessarily increase.

In an example, in the inference of the generative reverse diffusion model trained with a semiconductor pattern image, from a start step of a reverse process until changes in images corresponding to an intermediate step of restoration decrease below a predetermined standard, the first restoration method of adding random noise for each time step is adopted such that a sufficient diversity of generation results is secured, and when a step in which the changes in the images corresponding to the intermediate step of restoration decrease below the predetermined standard (for example, a step of determining that the overall form of an image has been completed to some extent, or a step of determining that the semantic feature of the image has been established to some extent) is reached, the second restoration method of increasing the interval of time steps and no longer adding random noise is adopted, and thus, an inference speed may be increased and computing resources may be saved. In particular, if only the first restoration method is applied for all time steps, the noise added for each time step may not be sufficiently removed once the last restoration step is complete to provide a final generation result and may remain in the final generation result, which may cause a problem in which the remaining noise may not be elaborate when generating contours. If only the second restoration method is applied for all time steps, a problem may occur in which a diversity of the final generation result may not be secured. Rather, various embodiments at least the first restoration method and the second restoration method, as non-limiting example, may be utilized, thereby reducing or minimizing any noise that may remain in the final generation result, and/or with diversity being accomplished, thereby not only generating an elaborate semiconductor pattern but also improving the performance efficiency compared to previous approaches.

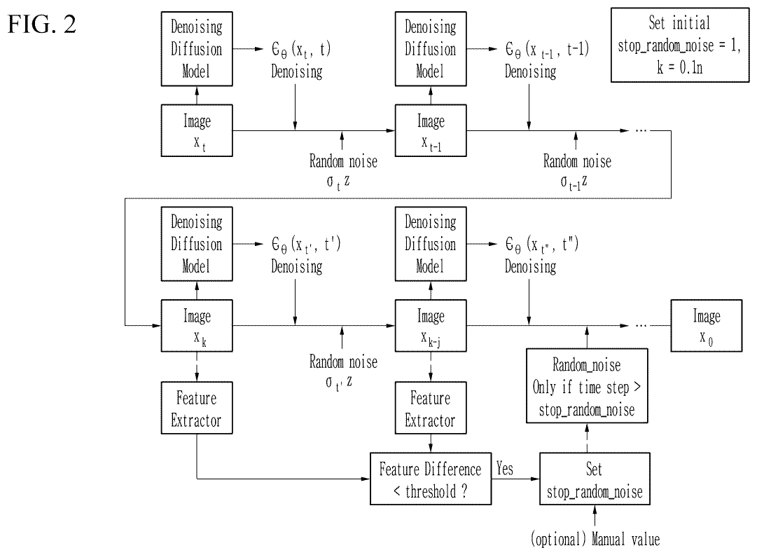

FIG. 2 illustrates an example method with semiconductor pattern generation according to one or more embodiments.

Referring to FIG. 2, an image xₜ₋₁ may be restored from an image xₜ in a reverse process of a generative reverse diffusion model (or a denoising diffusion model) based on a first restoration method. Specifically, the generative reverse diffusion model performs denoising on the image xₜ as expressed in ε_{θ}(xₜ, t), and random noise is added to the image xₜ as expressed in σₜ z so that the image xₜ₋₁ may be restored. Subsequently, image restoration in a subsequent step from the image xₜ₋₁ may be repeated, and then eventually after further steps an image xₖ may be restored.

After the image xₖ is restored, feature extraction may be performed on the image xₖ. Subsequently, image restoration in subsequent steps from the image xₖ (e.g., after the denoising based on ε_{θ}(x_{t′}, t′) and adding of noise σ_{t′}z) may be repeated and then, an image xₖ₋ⱼ may eventually be restored, and after the image xₖ₋ⱼ is restored, feature extraction may be performed on the image xₖ₋ⱼ. When features extracted with respect to the image xₖ and the image xₖ₋ⱼ are compared and a difference in the features does not meet a predetermined threshold (e.g., when it is determined that similarity between the image xₖ and the image xₖ₋ⱼ is a predetermined level or more), restoration may be repeated (e.g., starting with the restoration of the image xₖ₋ⱼ based on ε_{θ}(x_{t″}, t″)) until an image x₀ is restored from the image xₖ₋ⱼ, without adding random noise, based on a second restoration method different from the first restoration method.

In some embodiments, a variable that may store in memory the value of a time step at which the reverse process of the generative reverse diffusion model proceeds may be set. The computing device 10 may compare a value stored in memory representing a time step of the current step in the reverse process with the value stored in the variable. When the value representing the time step of the current step is greater than the value stored in the variable, a next step image may be restored by performing denoising on a current step image based on the first restoration method and then adding random noise. Unlike this, when the value representing the time step of the current step is less than or equal to the value stored in the variable, the next step image may be restored by performing only denoising on the current step image based on the second restoration method that is different from the first restoration method.

Specifically, the reverse process may proceed with time steps of a total of n steps (where n is an integer greater than 1), and the computing device 10 may restore the (n−1)-th step image from the n-th step image that starts the reverse process based on the first restoration method, and then repeat restoration until the k-th step image is eventually obtained from the (n−1)-th step image. Subsequently, the computing device 10 may perform feature extraction on the k-th step image to obtain a first feature, repeat restoration until the (k−j)-th step image is eventually obtained from the k-th step image based on the first restoration method, perform feature extraction on the (k−j)-th step image to obtain a second feature, and then determine the similarity between the k-th step image and the (k−j)-th step image based on the first feature and the second feature.

When it is determined that the similarity meets a predetermined level (e.g., is the predetermined level or more), the computing device 10 may set the value of the variable to k−j. Accordingly, when the value representing the time step of the current step is less than or equal to k−j stored in the variable, the first restoration method may be switched to the second restoration method.

When it is determined that the similarity fails to meet the predetermined level (for example, is less than the predetermined level), the computing device 10 may repeat restoration until the (k−j−m)-th step image (where m is an integer greater than 0) is eventually obtained from the (k−j)-th step image based on the first restoration method, and re-perform similarity determination on the (k−j−m)-th step image and a subsequent step image.

For example, the variable that may store in memory the value of the time step at which the reverse process of the generative reverse diffusion model proceeds may have the name “stop_random_noise”. 1 may be set in “stop_random_noise” as an initial value. As a result of performing feature extraction on the k-th step image to obtain the first feature, repeating restoration until the (k−j)-th step image is eventually obtained from the k-th step image based on the first restoration method, performing feature extraction on the (k−j)-th step image to obtain the second feature, and then determining the similarity between the k-th step image and the (k−j)-th step image based on the first feature and the second feature. When it is determined that the similarity meets a predetermined level (e.g., is the predetermined level or more), the computing device 10 may set the value of the variable “stop_random_noise” to k−j. Then, when the value representing the time step of the current step is less than or equal to k−j stored in the variable, the first restoration method may be switched to the second restoration method.

In some embodiments, the value of the variable may be set to a predetermined value indicating a ratio of time steps performed based on the first restoration method and the second restoration method. In this case, when similarity between images is not determined, and the value representing the time step of the current step is less than or equal to a value set as a predetermined value stored in the variable, the first restoration method may be switched to the second restoration method. For example, when “Manual value” is set in the variable “stop_random_noise”, similarity between images is not determined, and the value representing the time step of the current step is less than or equal to “Manual value” stored in the variable, the first restoration method may be switched to the second restoration method.

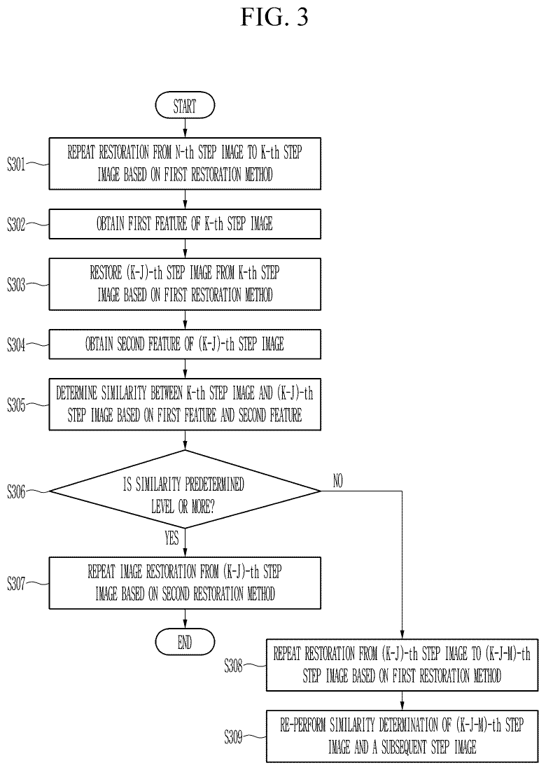

FIG. 3 is a flowchart of an example method with a semiconductor pattern generation according to one or more embodiments.

Referring to FIG. 3, the method of generating the semiconductor pattern according to an embodiment may include restoring the k-th step image from the n-th step image based on a first restoration method (performing restoration operations repeatedly from the n-th step image) (for example, performing a first sequence of the restorative operations of the generative model) (S301), obtaining a first feature of the k-th step image (S302), restoring the (k−j)-th step image from the k-th step image based on the first restoration method (for example, performing a second sequence of the restorative operations of the generative model) (S303), obtaining a second feature of the (k−j)-th step image (S304), determining similarity between the k-th step image and the (k−j)-th step image based on the first feature and the second feature (S305), and determining whether the similarity is a predetermined level or more (S306).

When it is determined that the similarity is the predetermined level or more, the method of generating the semiconductor pattern may perform repeating image restoration from the (k−j)-th step image based on a second restoration method (for example, performing a third sequence of the restorative operations of the generative model) (S307).

Unlike this, when it is determined that the similarity is not the predetermined level or more (for example, less than the predetermined level), the method of generating the semiconductor pattern may include restoring the (k−j−m)-th step image from the (k−j)-th step image based on the first restoration method (performing restoration operations repeatedly from the (k−j)-th step image) (S308), and re-performing similarity determination of the (k−j−m)-th step image and a subsequent step image (S309). For example, when the similarity determination of the (k−j−m)-th step image and the subsequent step image is determined to meet a predetermined minimum level (for example, be the predetermined level or more), the method of generating the semiconductor pattern may cease performing subsequent restorative operations based on a first restoration method and perform repeating image restoration from the subsequent step image based on a second restoration method (for example, performing the third sequence of the restorative operations of the generative model).

As non-limiting example, more specific details of the method of generating the semiconductor pattern may be referred to the descriptions above provided with reference to FIGS. 1 and 2, and thus, redundant descriptions have been omitted here.

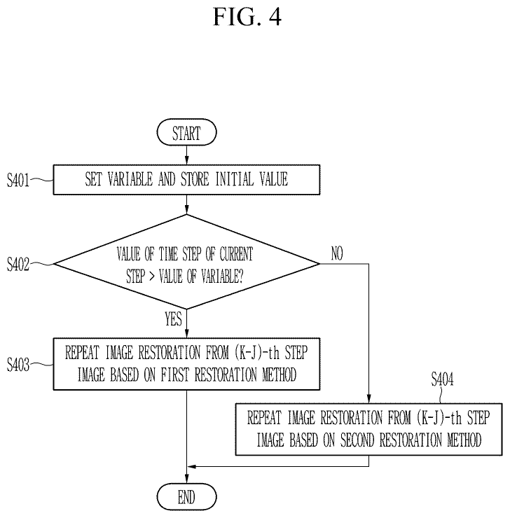

FIG. 4 is a flowchart of an example method with a semiconductor pattern generation according to one or more embodiments.

Referring to FIG. 4, the method of generating the semiconductor pattern according to an embodiment may include setting a variable capable of storing the value of a time step at which a reverse process of a generative reverse diffusion model proceeds and storing an initial value (S401) and determining whether the value of a time step of the current step is greater than the value of the variable (S402).

When it is determined that the value of the time step of the current step is greater than the value of the variable, the method of generating the semiconductor pattern may perform repeating image restoration from the (k−j)-th step image based on a first restoration method (S403).

Unlike this, when it is determined that the value of the time step of the current step is less than or equal to the value of the variable, the method of generating the semiconductor pattern may perform repeating image restoration from the (k−j)-th step image based on a second restoration method (S404).

More specific details of the method of generating the semiconductor pattern may be referred to the descriptions above provided with reference to FIGS. 1-3, and thus, redundant descriptions have been omitted here.

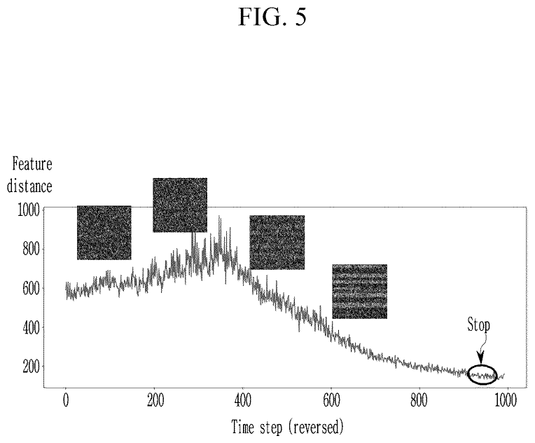

FIGS. 5 to 8 show example implementation results of semiconductor pattern generation according to one or more embodiments.

As previously explained, when only the first restoration method is implemented, the noise added for each time step may not be sufficiently removed from a final generation result and may remain in the final generation result, which may cause a problem in which the remaining noise may not be elaborate when generating contours (for example, a problem in which boundaries of straight lines may be uneven and the overall elaboration of a layout may deteriorate). Rather, when only the second restoration method is implemented, a problem may occur in which diversity of the final generation result is not secured.

FIG. 5 illustrates an example where a total of 1000 time steps were set, and where the value of the above example “stop_random_noise” was set to 5% of the total time steps. Accordingly, after a reverse process started, restoration of the image was repeated based on the first restoration method in a period corresponding to 950 time steps, and restoration of the image was repeated based on the second restoration method in a period corresponding to the remaining 50 time steps. As non-limiting examples, a vertical axis of FIG. 5 may refer to a feature distance. For example, a smaller feature distance may indicate a greater similarity between images.

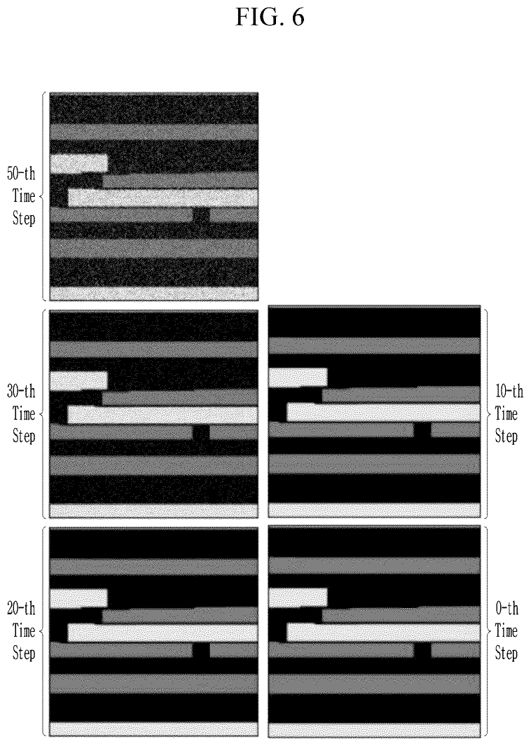

FIG. 6 illustrates example restoration results of an intermediate image, after 950 time steps among the total of 1,000 time steps have been performed according to the first restoration method, in 50-th, 30-th, 20-th, 10-th, and 0-th (final) time steps. In FIG. 6, it can be seen that it may be sufficient that only denoising was performed and random noise not added when the intermediate image is restored at each time step after cessation of the first restoration method. For example, sufficient diversity may have been secured by the first 950 time steps, so the remaining 50 time steps may focus on accelerating an inference speed rather than diversity. In particular, the length of one time step corresponding to the remaining 50 time steps was set to be longer than the length of one time step corresponding to the previous 950 time steps, which further accelerated the inference speed.

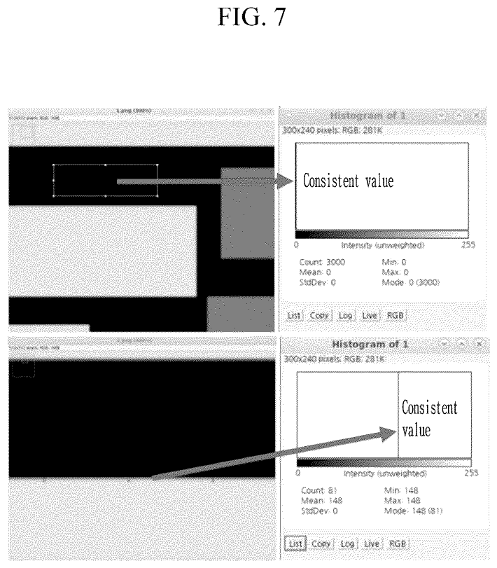

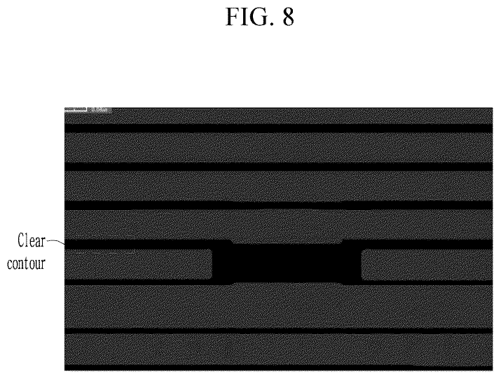

FIGS. 7 and 8 illustrate example final resultants obtained according to embodiments. As highlighted in FIG. 7, it can be seen that boundaries of straight lines were formed evenly to have a constant value. In FIG. 8, it can be seen that a layout contour was formed elaborately and clearly.

FIG. 9 illustrates an example electronic device according to one or more embodiments.

An electronic device 50 may include one or more processors 510, one or more memories 530, a user interface input device 540, a user interface output device 550, and one or more storage devices 560 that communicate over a bus 520. The electronic device 50 may also include a network interface 570 that is electrically connected to a network 40. The network interface 570 may transmit or receive signals to and from other entities over the network 40. In non-limiting examples, the electronic device 50 may be the computing device 10 of FIG. 1, or the one or more processors 510 and the one or more memories 530 may correspond to the computing device 10.

The one or more processors 510 may be or include various types of processors, such as any one or any combination of a Central Processing Unit (CPU), an Application Processor (AP), a Graphics Processing Unit (GPU), a Neural Processing Unit (NPU), a Micro Controller Unit (MCU), etc., or may be any semiconductor device that executes instructions stored in the one or more memories 530 or the one or more storage devices 560, for example. The one or more processors 510 may be configured to perform any one or any combination of operations described herein with respect to FIGS. 1-8, as non-limiting examples.

The one or more memories 530 and the one or more storage devices 560 may include various types of volatile or non-volatile storage media. For example, the one or more memories 530 may include read-only memory (ROM) 531 and random access memory (RAM) 532. In various embodiments, the one or more memories 530 may be located inside and/or outside the one or more processors 510, and the one or more memories 530 may be connected to the one or more processors 510 through various known means.

According to one or more embodiments, in an inference of a generative reverse diffusion model trained with a semiconductor pattern image, from a start step of a reverse process until changes in images corresponding to an intermediate step of restoration decrease below a predetermined standard, a first restoration method of adding random noise for each time step may be adopted such that a sufficient diversity of generation results is secured, and when a step in which the changes in the images corresponding to the intermediate step of restoration decrease below the predetermined standard (for example, a step of determining that the overall form of an image has been completed to some extent, or a step of determining that the semantic feature of the image has been established to some extent) is reached, a second restoration method of increasing the interval of time steps and stopping adding random noise may be adopted, and thus, an inference speed may be increased and computing resources may be saved.

The computing devices, electronic devices, processors, memories, user interface input devices, user interface output devices, storage devices, network interfaces, networks, and buses described herein, including descriptions with respect to FIGS. 1-9, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-9 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations).

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), a card type memory such as multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
generating a first image by performing a first sequence of restorative operations, of a generative model that is initially provided an input image, based on a first set restoration process, wherein the generative model is a circuitry pattern-based generative model having a first plurality of restorative operations;
generating a second image by performing a second sequence of restorative operations, of the generative model continuing from the first image, based on the first set restoration process; and
generating, dependent on a determined similarity between the first image and the second image, a final semiconductor pattern by performing a second plurality of restorative operations, of the generative model continuing from the second image, that include a third sequence of restorative operations of the generative model based on a second set restoration process that is different from the first set restoration process.

2. The method of claim 1,
wherein the first set restoration process includes performing a corresponding restoration operation of the generative model by performing denoising on a current image and then adding random noise to a result of the denoising, and
wherein the second set restoration process includes performing a different corresponding restoration operation of the generative model by performing the denoising without the adding of the random noise to the result of the denoising.

3. The method of claim 1, further comprising performing the determining of the similarity between the first image and the second image based on a first feature extracted from the first image and a second feature extracted from the second image, and determining whether the similarity meets a predetermined level,
wherein the generating of the final semiconductor pattern comprises:
when a result of the determining of whether the similarity meets the predetermined level is that the similarity meets the predetermined level, performing the third sequence of restorative operations of the generative model continuing from the second image, such that a final restorative operation of the third sequence is a final restorative operation of the generative model that outputs the final semiconductor pattern; and
when the result of the determining of whether the similarity meets the predetermined level is that the similarity does not meet the predetermined level, generating respective third images by performing subsequent restorative operations, of the second plurality of restorative operations continuing from the second image, based on the first set restoration process and prior to the third sequence of restorative operations.

4. The method of claim 3, wherein the generating of the final semiconductor pattern comprises, when a performed similarity determination between one of the respective third images and a subsequent one of the respective third images is determined to meet a predetermined minimum level, ceasing the performing of the subsequent restorative operations and begin performing the third sequence of restorative operations of the generative model continuing from the subsequent one of the respective third images, such that the final restorative operation of the third sequence is the final restorative operation of the generative model that outputs the final semiconductor pattern.

5. The method of claim 1, further comprising performing the determining of the similarity between the first image and the second image by:
extracting a first feature from the first image and extracting a second feature from the second image;
converting the first feature into a first feature vector and converting the second feature into a second feature vector;
measuring the similarity between the first image and the second image by comparing the first feature vector with the second feature vector;
assigning a similarity score to a result of the measuring, and determining whether the similarity score meets a predetermined threshold; and
in response to the similarity score being determined to meet the predetermined threshold, determining that the first image and the second image are similar, and performing the third sequence of restorative operations of the generative model continuing from the second image, such that a final restorative operation of the third sequence is a final restorative operation of the generative model that outputs the final semiconductor pattern.

6. The method of claim 5, wherein the measuring of the similarity between the first image and the second image includes measuring a similarity between the first feature vector and the second feature vector through at least one of Euclidean Distance, Cosine Similarity, and Manhattan Distance-based measurements.

7. The method of claim 1,
wherein the first plurality of restorative operations of the generative model are respectively differently timed restorative operation steps, from a first restorative operation step to intermediary restorative operation steps to a final restorative operation step that corresponds to a final restorative operation of the generative model, and
wherein a sequencing of corresponding restorative operations, of the generative model when implemented based on the first set restoration process, is according to a first time step length that is different from a second time step length of the second set restoration process that defines a sequencing of other corresponding restorative operations of the generative model when implemented based on the second set restoration process.

8. The method of claim 7, wherein the second time step length is longer than the first time step length.

9. The method of claim 1, further comprising performing the determining of the similarity between the first image and the second image by respectively extracting a first feature from the first image and a second feature from the second image and comparing the first feature to the second feature,
wherein the first feature and the second feature each include at least one of color, texture, shape, boundary, detailed pattern, and feature point.

10. The method of claim 1, further comprising performing the determining of the similarity between the first image and the second image by respectively extracting a first feature from the first image and a second feature from the second image and comparing the first feature to the second feature,
wherein the first feature and the second feature each include a semantic feature.

11. The method of claim 1, further comprising:
setting a first variable in a memory to store a value of a time step at which a restorative operation of the generative model based on the second set restoration process is set to proceed;
maintaining a second variable in the memory to represent decrementing integer values for current time steps of respective restorative operations of the generative model as the plurality of restorative operations are being performed; and
performing the third sequence of the generative model when the second variable reaches the first variable.

12. A processor-implemented method, the method comprising:
setting a variable in a memory to store a value of a time step at which a reverse process of a diffusion model is configured to proceed, wherein the diffusion model is trained with a semiconductor pattern image; and
generating a final semiconductor pattern by executing the reverse process of the diffusion model, including:
comparing a first value representing a time step of a current step in the reverse process of the diffusion model with the value stored in the variable;
when the first value is greater than the value stored in the variable, restoring a next step image by performing denoising on a current step image and adding random noise to a result of the denoising performed on the current step image, based on a first set restoration process; and
when the first value is less than or equal to the value stored in the variable, restoring the next step image by performing the denoising on the current step image, without performing the adding of the random noise to the result of the denoising, based on a second set restoration process different from the first set restoration process.

13. The method of claim 12, wherein the setting of the value of the variable includes setting the value of the variable to a predetermined value representing a ratio of time steps performed based on the first set restoration process and the second set restoration process.

14. The method of claim 12,
wherein the reverse process of the diffusion model is configured to proceed with a total set number of time steps,
wherein the method further comprises:
generating a k-th step image from an n-th step image by repeating, a first reverse restoration process of the diffusion model based on the first set restoration process, wherein n is an integer greater than 1 and k is an integer of n−1 or less;
generating a (k−j)-th step image from the k-th step image by another repeating of the first reverse restoration process of the diffusion model based on the first set restoration process, wherein j is an integer greater than 0; and
determining a similarity between the k-th step image and the (k−j)-th step image by extracting a first feature from the k-th step image, extracting a second feature from the (k−j)-th step image, and comparing the first feature and the second feature, and
wherein the setting of the variable in the memory to store the value of the time step includes, when it is determined that the similarity is a predetermined level or more, setting the value of the variable to k−j.

15. The method of claim 14, further comprising:
when it is determined that the similarity is less than the predetermined level, generating a (k−j−m)-th step image from the (k−j)-th step image by an additional repeating of the first reverse restoration process of the diffusion model based on the first set restoration process, wherein m is an integer greater than 0; and
performing a similarity determination between the (k−j−m)-th step image and a subsequent step image.

16. The method of claim 15, further comprising:
when it is determined that the similarity between the k-th step image and the (k−j)-th step image fails to meet a predetermined minimum level, specifying a value of m as a value that is a predetermined minimum value or more.

17. A computing device, comprising:
one or more processors configured to:
generate a first image through performance of a first sequence of restorative operations, of a generative model that is initially provided an input image, based on a first set restoration process, wherein the generative model is a circuitry pattern-based generative model having a first plurality of restorative operations;
generate a second image through performance of a second sequence of restorative operations, of the generative model continuing from the first image, based on the first set restoration process; and
generate, dependent on a determined similarity between the first image and the second image, a final semiconductor pattern through performance of a second plurality of restorative operations, of the generative model continuing from the second image, that include a third sequence of restorative operations of the generative model based on a second set restoration process that is different from the first set restoration process.

18. The computing device of claim 17,
wherein the first set restoration process includes performance of a corresponding restoration operation of the generative model through performance of a denoising on a current image and then an addition of random noise to a result of the denoising, and
wherein the second set restoration process includes performance of a different corresponding restoration operation of the generative model through performance of the denoising without the addition of the random noise to the result of the denoising.

19. The computing device of claim 17,
wherein the one or more processors are further configured to perform the determination of the similarity between the first image and the second image based on a first feature extracted from the first image and a second feature extracted from the second image, and determining whether the similarity meets a predetermined level, and
wherein, for the generating of the final semiconductor pattern, the one or more processors are configured to:
when a result of the determining of whether the similarity meets the predetermined level is that the similarity meets the predetermined level, perform the third sequence of restorative operations of the generative model continuing from the second image, such that a final restorative operation of the third sequence is a final restorative operation of the generative model that outputs the final semiconductor pattern;
when the result of the determining of whether the similarity meets the predetermined level is that the similarity does not meet the predetermined level, generate respective third images by performing subsequent restorative operations, of the second plurality of restorative operations continuing from the second image, based on the first set restoration process and prior to the third sequence of restorative operations; and
when a performed similarity determination between one of the respective third images and a subsequent one of the respective third images is determined to meet a predetermined minimum level, cease the performing of the subsequent restorative operations and perform the third sequence of restorative operations of the generative model continuing from the subsequent one of the respective third images.

20. The computing device of claim 17, wherein the one or more processors are further configured to perform the determination of the similarity between the first image and the second image through:
an extraction of a first feature from the first image and an extraction of a second feature from the second image;
a conversion of the first feature into a first feature vector and a conversion of the second feature into a second feature vector;
a measurement of the similarity between the first image and the second image through a comparison of the first feature vector with the second feature vector;
an assignment of a similarity score to a result of the measuring, and determine whether the similarity score meets a predetermined threshold; and
in response to the similarity score being determined to meet the predetermined threshold, a determination that the first image and the second image are similar, and a performance of the third sequence of restorative operations of the generative model continuing from the second image, such that a final restorative operation of the third sequence is a final restorative operation of the generative model that outputs the final semiconductor pattern.

21. The computing device of claim 20, wherein, for the measuring of the similarity between the first image and the second image, the one or more processors are configured to measure a similarity between the first feature vector and the second feature vector through at least one of Euclidean Distance, Cosine Similarity, and Manhattan Distance-based measurements.
